(19) United States
(12) Patent Application Publication
(10) Pub. No.: US 2004/0089943 A1
(43) Pub. Date: May 13, 2004

(54) Electronic control device and method for manufacturing the same

(76) Inventors: Masato Kirigaya, Kariya-city (JP); Arihiro Kamiya, Anjo-city (JP)

Correspondence Address: POSZ & BETHARDS, PLC, 11250 ROGER BACON DRIVE, SUITE 10, RESTON, VA, 20190, US

(21) Appl. No.: 10/701,443

(22) Filed: Nov. 6, 2003

(30) Foreign Application Priority Data
Nov. 7, 2002 (JP) 2002-324042
Nov. 13, 2002 (JP) 2002-329313

(51) Int. Cl. H01L 21/44; H01L 23/02

(52) U.S. Cl. 257/723; 257/685; 257/686; 438/109; 257/704; 438/125; 438/110

(57) ABSTRACT

An electronic control device includes first and second ceramic substrates housed in a case. The first ceramic substrate has electronic components including a semiconductor component mounted on its surface. The second ceramic substrate is fixed to the top face of the semiconductor component. The second ceramic substrate has electronic components mounted on its bottom surface. A connecting member having wiring members is arranged between the first and the second ceramic substrates. The first ceramic substrate is electrically connected with the second ceramic substrate via the wiring members.

### CROSS REFERENCE TO RELATED APPLICATION

This application is based on and incorporates herein by reference Japanese Patent Applications No. 2002-324042 filed on Nov. 7, 2002 and No. 2002-329313 filed on Nov. 13, 2002.

### FIELD OF THE INVENTION

The present invention relates to an electronic control device and a method for manufacturing the electronic control device.

### BACKGROUND OF THE INVENTION

An electronic control unit (ECU) is used in a vehicle for controlling an engine or other devices installed on the vehicle. The ECU includes a substrate and semiconductor components having connecting terminals mounted on the substrate. The connection structure of the substrates that improves the reliability in connection of the components with the substrate and the thermal dissipation of the components is proposed in Japanese patent application No. 2001-77527. In this structure, the connecting terminals located at the corners are covered with a nonconductive resin.

The nonconductive resin deteriorates under high temperature and humidity conditions. The deteriorated resin loses protection effect resulting in cracks in solder and removals of lands from the substrate. The nonconductive resin deteriorates even more under condition that the temperature significantly changes. As a result, long-term reliability in connections of the components are not assured.

Heat produced by the components is released only from solder bumps to the substrate in this structure, namely, thermal resistance is high, and that causes a temperature increase in the components. The increased temperature in the components may cause malfunctions of the components.

Furthermore, the substrate is housed by a case and is electrically connectable to external devices via connectors. Terminal pins of the connector connectable to external devices are usually connected with the substrate by wire bonding. Wires used in the wire bonding take up space and limit miniaturization of the ECU.

### SUMMARY OF THE INVENTION

The present invention therefore has an objective to provide an electronic control device that has a reliable connection structure between semiconductor components and a substrate and high heat dissipation and a method for manufacturing the electronic control device.

An electronic control device of the present invention includes the first and the second ceramic substrate. The second ceramic substrate is fixed to the top face of a semiconductor component mounted on the first ceramic substrate. The thermal expansion coefficient of the semiconductor component is virtually close to that of the ceramic substrate. As a result, the thermal stress applied to soldering portions at the connections between the first ceramic substrate and connecting pins decreases and the reliability of the connections improves.

The second ceramic substrate fixed to the top surface of the semiconductor component functions as a heat sink. The second ceramic substrate can release a large amount of heat produced by the semiconductor component. With the above-described structure, the connection reliability and the heat dissipation of the semiconductor component improve.

The second ceramic substrate is mounted on the top face of the semiconductor component and then the semiconductor component is mounted on the first ceramic substrate. Self-alignment effect melting solder is produced by melting solder. As a result, precise alignment is not necessary and that makes the assembling of the ECU easier.

The present invention has another objective to provide an electronic control device that has a connection structure that takes less space between a substrate and connecting pins. An electronic control device of the present invention has electrodes on one of substrate surfaces. A base end of each connecting pin is connected to the electrode.

The connecting pins are passed through pin holes formed in a case of the electronic control device so that the other end is exposed to the outside. With this configuration, space for bonding wires that connect the substrate to the connecting pins are not required, that is, the ECU can be reduced in size.

### BRIEF DESCRIPTION OF THE DRAWINGS

The above and other objectives, features and advantages of the present invention will become more apparent from the following detailed description made with reference to the accompanying drawings. In the drawings:

FIG. 1 is a cross-sectional view of an electronic control unit (ECU) according to the first embodiment of the present invention;

FIG. 2 is a perspective view of the ECU according to the first embodiment;

FIG. 3 is an exploded view of the ECU according to the first embodiment;

FIG. 4 is a cross-sectional view of an electronic control unit (ECU) according to the second embodiment of the present invention;

FIG. 5 is an exploded view of the ECU according to the second embodiment;

FIG. 6 is an enlarged partial view of the ECU according to the second embodiment; and

FIG. 7 is an enlarged partial view of the ECU according to a modification of the second embodiment.

### DETAILED DESCRIPTION OF THE PREFERRED EMBODIMENT

The preferred embodiments of the present invention will be explained with reference to the accompanying drawings. In the drawings, the same numerals are used for the same components and devices.

[First Embodiment]

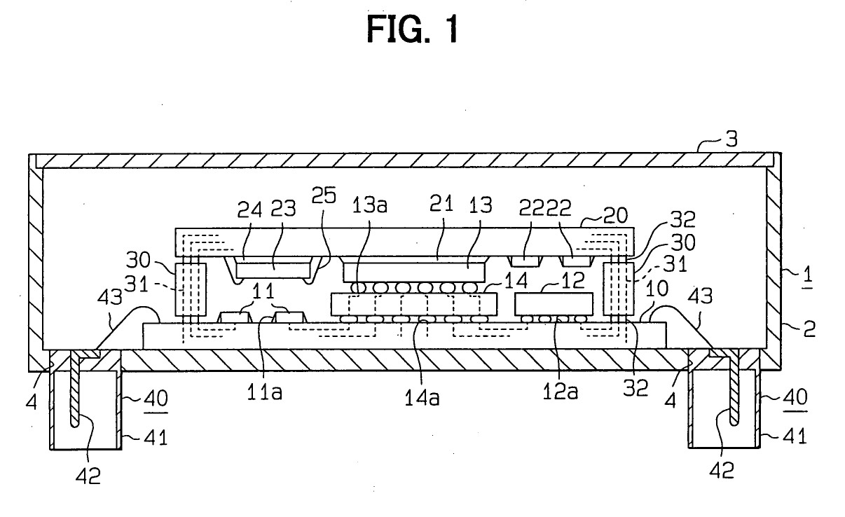

Referring to FIG. 1, an electronic control unit (ECU) has a case 1 constructed of a case body 2 and a cover 3. The case body 2 is made of aluminum and in the form of a box having an opening on its top side. The opening is covered with a cover 3.

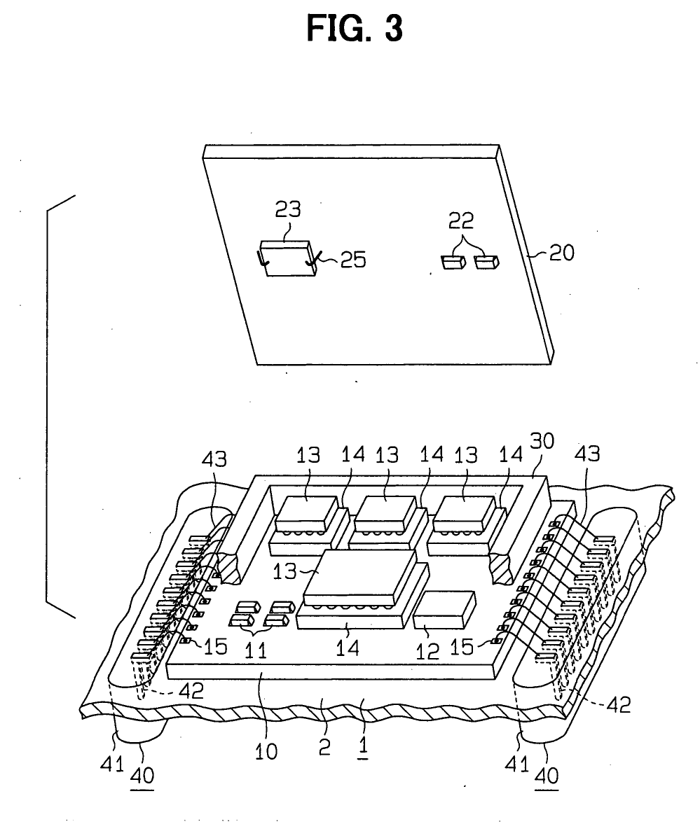

A ceramic substrate 10 (first ceramic substrate) is arranged and fixed at an inside bottom of the case body 2 with an insulating adhesive 4. The first ceramic substrate 10 is a multilayered ceramic substrate. As shown in FIG. 3, the first substrate 10 has electronic components 11-13 mounted on its top surface. The electronic components 11-13 are chip capacitors 11, a flip chip type electronic component 12, and chip size packages (CSPs) 13.

The CSPs 13 are semiconductor components and mounted via interposers 14, which are flip chip type electronic components used as mounts. More specifically, the interposers 14 are soldered to the substrate 10, and then the CSPs 13 are soldered to the interposers 14. The interposers 14 also function as wiring members that electrically connect bumps (solder balls) of the CSPs 13 with pads 15 formed on the substrate 10. Four CSPs 13 are mounted on the substrate 10.

The top faces of the CSPs 13 are positioned higher than the chip capacitors 11 and the flip chip 12 because the CSPs 13 are mounted on the first substrate 10 via the interposers 14. The interposers 14 are made of the same ceramic material as the first substrate 10, such as alumina. Therefore, the thermal expansion coefficient of the interposers 14 is close to that of the first substrate 10, and only a small amount of thermal stress is applied between the interposers 14 and the first substrate 10.

Another ceramic substrate 20 (second ceramic substrate) is fixed to the top faces of the CSPs 13 mounted on the first substrate 10 via adhesive layers 21. The second ceramic substrate 20 is a multi-layered ceramic substrate used as a circuit board. Since the CSPs 13 are located higher than the other components 11, 12 on the first substrate 10, the second substrate 20 can be easily arranged.

Referring to FIG. 3, the ceramic substrate 20 has electronic components 22, 23 on its bottom surface. The electronic components 22 are chip capacitors 22. The electronic component 23 is a bare chip 23 fixed to the second substrate 20 via an adhesive layer 24 and electrically connected with the ceramic substrate 20 via gold (Au) bonding wires 25. The bare chip 23 can be mounted on the first substrate 10.

A connecting member 30 is arranged between the first and the second substrates 10 and 20 for electrical connection between the first and the second substrate 10 and 20. The connecting member 30 is made in the form of a quadrilateral frame and positioned so that the electronic components 11, 12, 13, 22, 23 are located inside the connecting member 30. The main body of the connecting member 30 is made of a ceramic material (insulator). A number of wiring members (conductors) 31 are passed through the connecting member 30 in the vertical direction. The wiring members are soldered to the first and the second substrates 10 and 20. Thus, the first and the second substrates 10 and 20 are electrically connected to each other via the wiring members 31.

A large-scale electronic circuit can be formed on the ceramic substrates 10 and 20 that are electrically connected to each other. Furthermore, the connecting member 30 that connects the first and the second substrates 10 and 20 is made of the same ceramic material as the first and the second substrates 10 and 20. Therefore, only a small amount of thermal stress is applied to soldering portions 32 and the reliability of the connection improves.

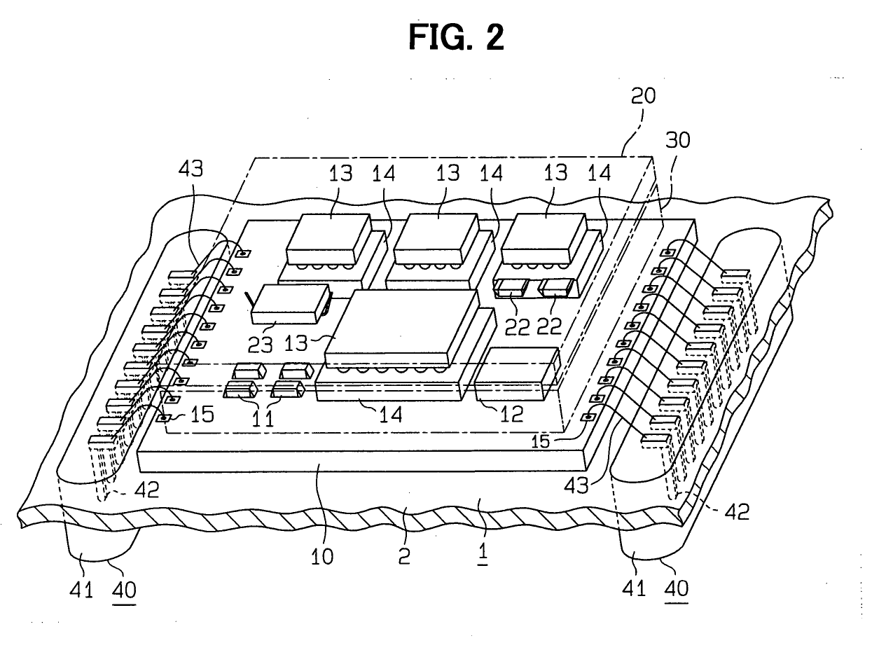

Referring to FIG. 2, a number of pads 15 are formed on the top surface of the ceramic substrate 10 along the opposite edges (left and right edges in FIG. 2). The case body 2 has connector holes 4 at positions adjacent to the opposite edges along which the pads 15 are formed when the ceramic substrate 10 is inserted in the case body 2. A connector 40 constructed of a connector housing (socket) 41 and a connector pins 42. The connector 40 is inserted in each connector hole 4 and fixed. The connector housing 41 has a tubular shape with a lid. The connector pines 42 penetrate the lid of the connector housing 41 so that they are supported with the lid. The connector pines 42 are electrically connected with the pads 15 via bonding wires 43.

The connector 40 is connected to ends of wires via a connector of devices to which the ECU is connected. The wires are connected to a battery, sensors, and engine control actuators. The ECU detects operating conditions of the engine based on sensor signals and performs various operations. The ECU drives the engine control actuators including injectors and igniters for operating the engine under the most favorable conditions.

A method for assembling the ECU will be explained. In the first step, the electronic components 11-13 are mounted on the top surface of the first substrate 10, and the electronic components 22 and 23 are mounted on the second substrate 20. Moreover, the connecting member 30 is arranged on the top surface of the first substrate 10.

In the second step, the second substrate 20 is fixed to the top faces of the CSPs 13. By mounting the CSPs 13 on the first substrate 10 before fixing the second substrate 20 to the CSPs 13, self-alignment effect is produced by melting solder. As a result, precise alignment is not necessary and that makes the assembling of the ECU easier.

Soldering the electronic components 11-13, 22, 23 and the wiring members 31 to the first and the second substrates 10 and 20 are performed by reflow soldering. As a result, steps of the assembling are reduced resulting in reduction in manufacturing cost.

In the third step, the first substrate 10 is fixed to the case body 2 and the connectors 40 are attached. Furthermore, the pads 15 and the connector pins 42 are connected together via the wires 43 by wire bonding. Then, the cover 3 is attached to the case body 2 and the assembling process of the ECU is completed.

It is preferable to use lead-free solder for the connecting layers 21 to reduce environmental burden. For the same reason, it is preferable to use lead-free solder for soldering the chip capacitors 11, 12 to the ceramic substrates 10 and 20 as well as for the connecting layers 24.

If alumina is used for the first substrate 10 and the interposers 14, their thermal expansion coefficients are both approximately 7×10⁻⁶/° C. Thus, only a small amount of thermal stress is applied to the soldering portions 14a. On the other hand a large amount of thermal stress is applied to the soldering portions 13a between the CSPs 13 and the interposers 14. The thermal stress is caused by a difference in the thermal expansion coefficient between the CSP 13 and the interposer 14. The CSPs 13 are made of a semiconductor (silicon) having approximately 2×10⁻⁶/° C. of thermal expansion coefficient. The interposers 14 are made of alumina having approximately 7×10⁻⁶/° C. of thermal expansion coefficient. Therefore, the difference in the thermal expansion coefficient is approximately 5×10⁻⁶/° C. The thermal stress is especially large around corners of the CSP 13 and adjacent bumps. If the CSPs 13 are large in size, the thermal stress is also large.

Semiconductor components have been increasing in size as demands for more functionality increase. The thermal stress is an issue in reliability of the connections. To resolve this issue, the second substrate 20 is fixed to the top face of the CSPs 13 so that the thermal expansion coefficient of the CSP 13 is virtually close to that of the first substrate 10. With this configuration, only a small amount of thermal stress is applied to the soldering portions 13a and cracks in solder and land removal are less likely to occur. As a result, long-term reliability in connection of the CSPs 13 improves.

The second substrate 20 functions as a heat sink. Thus, the heat dissipation of the CSPs 13 improves and the malfunction of the CSPs 13 is less likely to occur. The heat produced in the CSPs 13 is dissipated by the second substrate 20. As a result, the heat resistances around the CSPs 13 decrease, and the CSP 13 maintains reliable connections and performance under high temperature conditions.

[Second Embodiment]

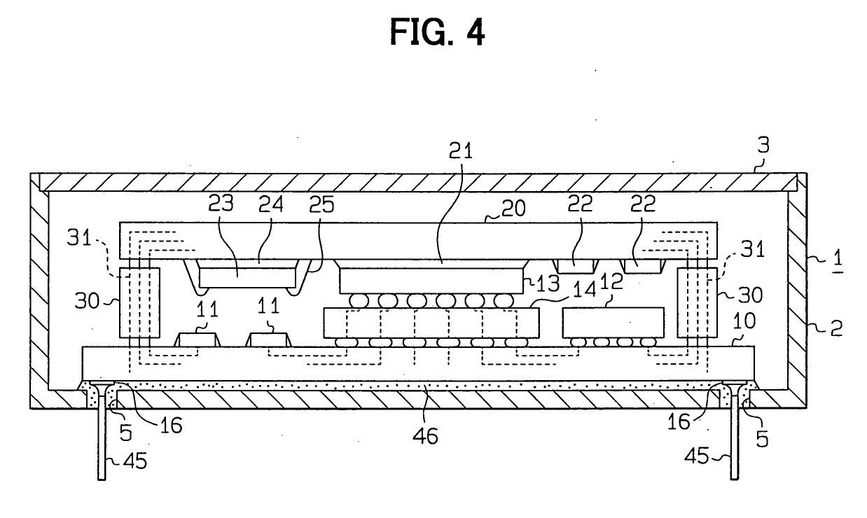

Referring to FIG. 4, an electronic control unit (ECU) has a case 1 constructed of a case body 2 and a cover 3. The case body is made of aluminum and in the form of a box having an opening on its top side. The opening is covered with a cover 3.

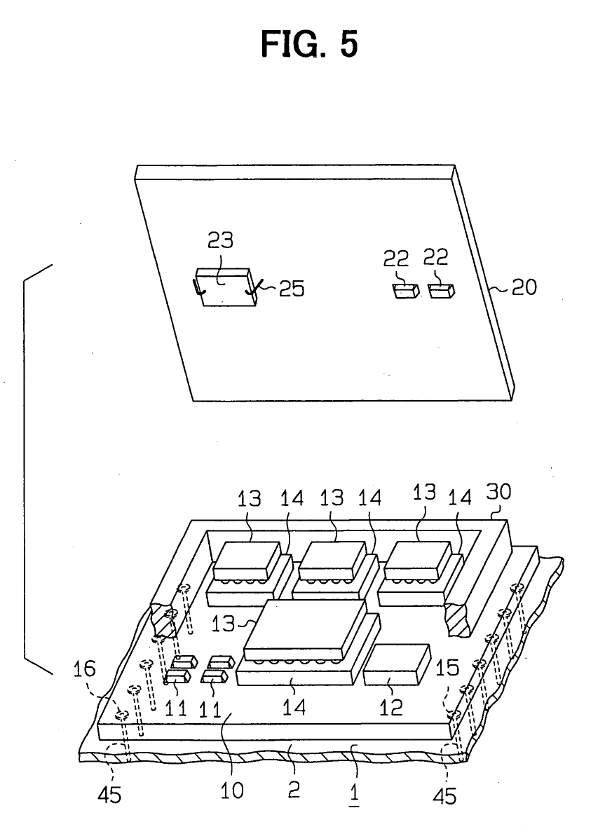

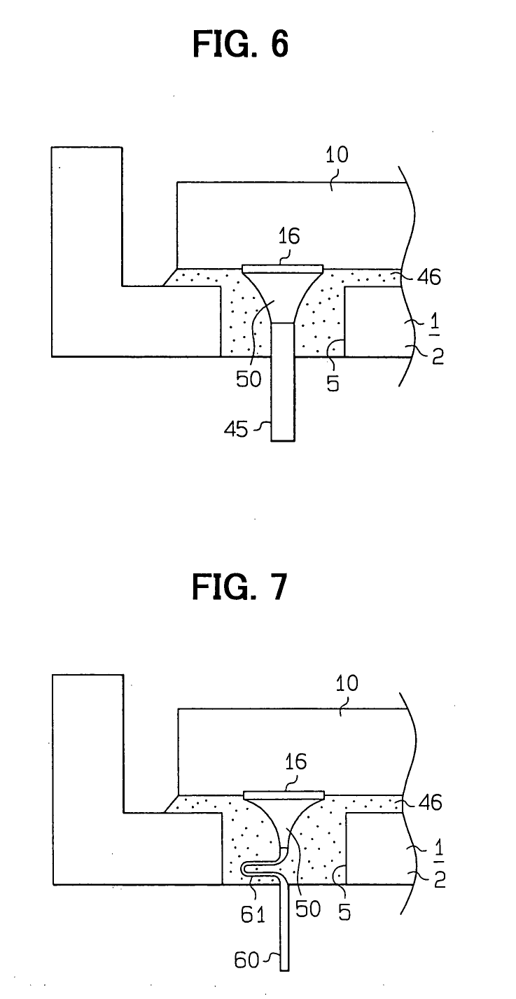

A substrate 10 (first substrate) is arranged at an inside bottom of the case body 2 with an insulating adhesive 46. The substrate 10 is a multilayered ceramic substrate. As shown in FIG. 5, the substrate 10 has chip capacitors 11, a flip chip type electronic component 12, and chip size packages (CSPs) 13 on its top surface.

The CSPs 13 are mounted via interposers 14, which are flip chip type electronic components used as mounts. More specifically, the interposers 14 are soldered to the substrate 10 and the CSPs 13 are soldered to the interposers 14. The interposers 14 also function as wiring members that electrically connect bumps (solder balls) of the CSP 13 with pads 16 formed on the substrate 10. Four CSPs 13 are mounted on the substrate 10.

Another substrate 20 (second substrate) is arranged on the top faces of the CSPs 13 and fixed with adhesive layers 21. The substrate 20 is a multilayered ceramic substrate. The substrate 20 has electronic components 22, 23 mounted on its bottom surface. The electronic components 22 are chip capacitors 22. The electronic component 23 is a bare chip 23 fixed to the second substrate 20 via an adhesive layer 24 and electrically connected with the ceramic substrate 20 via bonding wires 25.

A connecting member 30 is arranged between the first and the second substrates 10 and 20. The connecting member 30 is formed in a quadrilateral frame shape and positioned so that the electronic components 11, 12, 13, 22, 23 are located inside the connecting member 30. The main body of the connecting member 30 is made of a ceramic material (insulator). A number of wiring members (conductors) 31 are passed through the connecting member 30 in the vertical direction. The wiring members are soldered to the first and the second substrates 10 and 20. Thus, the first and the second substrates 10 and 20 are electrically connected to each other via the wiring members 31.

A number of electrodes (pads) 16 are formed on the top surface of the first substrate 10 along the opposite edges (left and right edges in FIG. 5). The electrodes 16 are electrically connected to electronic circuits on the top surface of the first substrate 10 via through holes or via holes.

The case body 2 has pin holes 5 on the bottom side at positions corresponding to the electrodes 16. A connecting pin 45 is passed through each pin hole 5 and the top of the pin 45 is soldered to the electrode 16. The other end of the pin 45 is exposed to the outside. The pin 45 is fixed to the case body 2 with an isolating adhesive 46 around the pin hole 5. The adhesive 46 is made of low melting glass material, such as a borosilicate glass material.

The ECU is connectable to external devices via the connecting pins 45 that are electrically connected to the first substrate 10. More specifically, the connecting pins 45 are connected with ends of wires that are connected with a battery, sensors, and engine control actuators via connectors. The ECU detects operating conditions of the engine based on sensor signals and performs various operations for driving actuators including injectors and igniters so that the engine operates under the most favorable conditions.

The electrodes (pads) 16 are provided on one side of the first substrate 10 and the connecting pins 45 are directly connected to the electrodes 16 with solder 50. Moreover, the connecting pins 45 are passed through the pin holes 5 and their ends are exposed to the outside. Since the connecting pins 45 are directly connected to the electrodes 16, spaces for bonding wires are not required. This provides an advantage in miniaturization of the ECU.

The solder 50 is used for connection between the connecting electrodes 16 and the connecting pins 45. The adhesives 46 are used for connecting between the connecting pins 45 and the case 1, or between the case 1 and the first substrate 10. Namely, the adhesives 46 bond and insulate the first substrate 10 and the case 1, and the connecting pins 45 and the case 1. As a result, the electronic components and the case 1 are electrically isolated. Furthermore, the adhesives 46 reduce external loads applied to the connecting pins 45. Therefore, the connection between the electrodes 16 and the first substrate 10, between the solder 50 and electrodes 16, and between the connecting pins 45 and the solder 50 are less likely to become loose.

The connecting pins 45 are fixed to the case 1 around the pin holes 5 with the adhesives 46. Thus, the connecting pins 45 are electrically isolated from the case 1. Furthermore, the insulating adhesives 46 reduce external loads applied to the connecting pins 45. Therefore, the durability improves.

Resistors are printed on the bottom surface of the substrate. Since the printed resistors are sensitive to humidity, an overcoat glass is required over the surface of the first substrate 10 to protect the printed resistors from humidity. The borosilicate glass is used as an insulating adhesive 46 and it function as an overcoat glass. Namely, an extra overcoat glass is not required. This is an advantage in terms of cost. However, the insulating adhesive 46 is not limited to the borosilicate glass material. Any materials can be used as long as they have adhesion, isolation, and durability.

To increase the durability, a connecting pin 60 having curved portion 61 shown in FIG. 7 may be used instead of the connecting pin 45. The curved portion 61 is positioned in the isolating adhesive 46. The curved portion 61 is formed by bending press. With this configuration, external loads are absorbed by the curved portion 61. Therefore, the durability of the connecting pins 60 and the first substrate 10 increases. Even though the connecting pins 60 are directly connected to the first substrate 10 and the external loads are directly applied to the connecting pins 60 and the first substrate 10, the external loads are absorbed by the curved portion 61. As a result, the durability increases.

The present invention should not be limited to the embodiment previously discussed and shown in the figures, but may be implemented in various ways without departing from the spirit of the invention. For example, the chip capacitor 22 and the bare chip 23 may be mounted on the top face of the second substrate 20. In other words, the chip capacitor 22 and the bare chip 23 can be mounted either side of the ceramic substrate 20. This provides an advantage in miniaturization of the ECU.

The CSPs 13 may be directly mounted on the first substrate 10 without the interposers 14. However, the direct mount of the CSPs 13 to the first substrate 10 should be limited to small-size CSPs 13. This is because the larger amount of thermal stress is applied to the soldering portions 13a as the sizes of the CSPs 13 become larger, and the reliability in connection decreases.

Spaces around the soldering portions 32 may be hermetically-sealed with a low-melting glass material after soldering. The sealing blocks moisture from entering, and improves long-term reliability in connections and performance of the components. Furthermore, the sealing reduces the chances of lead leaks to the outside even when lead eutectic solder is used in soldering portions 32, 14a, 13a, 12a, 11a. Thus, the environmental burdens can be reduced.

A flexible substrate can be used for electrical connection between the first and the ceramic substrates 10 and 20. By using the flexible substrate, the thermal stresses applied to the soldering portions are reduced and the reliability in connection is improved. Moreover, the assembling process is simplified.

A ball grid array (BGA), which is a facedown bonding type semiconductor component, or flip chip type electronic component may be used for the semiconductor component 13.

What is claimed is:

1. An electronic control device comprising first and second ceramic substrates on which electronic components, including a semiconductor component, are mounted, the ceramic substrates housed by a case, wherein the second ceramic substrate is fixed to a top face of the semiconductor component mounted on the first ceramic substrate.

2. The electronic control device according to claim 1, wherein the second ceramic substrate has an electronic component on at least one of surfaces thereof.

3. The electronic control device according to claim 2, wherein the first ceramic substrate is electrically connected with the second ceramic substrate.

4. The electronic control device according to claim 3, further comprising a connecting member arranged between the first and the second ceramic substrates, wherein:
the connecting member has a wiring member; and
the first ceramic substrate is electrically connected via the wiring member.

5. The electronic control device according to claim 3, wherein the first ceramic substrate is electrically connected with the second ceramic substrate via a flexible substrate.

6. The electronic control device according to claim 1, further comprising a flip chip type electronic component, wherein:
the semiconductor component is mounted to the first ceramic substrate via the flip chip type electronic component so that the top face of the semiconductor component is positioned higher than other electronic components.

7. The electronic control device according to claim 6, wherein the flip chip type electronic component is made of a ceramic material.

8. A method for manufacturing an electronic control device having electronic components, including a semiconductor component, mounted on a first and a second ceramic substrate, comprising:
mounting the semiconductor component on the first ceramic substrate; and
fixing the second ceramic substrate to a top face of the semiconductor component.

9. The method for manufacturing the electronic control device according to claim 8, wherein the mounting step and the fixing step are completed by reflow soldering along with mounting electronic components on the first and the second ceramic substrates.

10. An electronic control device comprising:
a substrate on which electronic components, including a semiconductor component, are mounted and having connecting pins electrically connected thereto for connecting the substrate to an external device; and
a case for housing the substrate, wherein
the connecting pins are electrically connected to the substrate via electrodes formed on one of the faces of the substrate by connecting base ends of the connecting pins to the electrodes, and
the connecting pins are passed through pin holes formed in the case and tips of the connecting pins are exposed to an outside.

11. The electronic control device according to claim 10, the connecting pins are fixed to the case by filling an isolating adhesive in the pin holes.

12. The electronic control device according to claim 11, wherein the isolating adhesive is made of a low-melting glass material.

13. The electronic control device according to claim 12, wherein the low-melting glass material is a borosilicate glass material.

14. The electronic control device according to claim 10, wherein each connecting pin has a curved portion

15. The electronic control device according to claim 10, wherein the circuit substrate is a ceramic substrate.
